(19) United States
(12) Patent Application Publication
(10) Pub. No.: US 2015/0248997 A1
(43) Pub. Date: Sep. 3, 2015

(54) MODIFIED LITHIUM COBALT OXIDE SPUTTERING TARGETS

(71) Applicants: CHI-FUNG LO, FORT LEE, NJ (US); PAUL GILMAN, SUFFERN, NY (US); DARRYL P. DRAPER, CONGERS, NY (US)

(72) Inventors: CHI-FUNG LO, FORT LEE, NJ (US); PAUL GILMAN, SUFFERN, NY (US); DARRYL P. DRAPER, CONGERS, NY (US)

(21) Appl. No.: 14/629,836

(22) Filed: Feb. 24, 2015

Related U.S. Application Data
(60) Provisional application No. 61/946,286, filed on Feb. 28, 2014.

(51) Int. Cl. H01J 37/34; H01M 4/525; C23C 14/08

(52) U.S. Cl. CPC H01J 37/3429; C23C 14/08; H01J 37/3417; H01M 4/525

(57) ABSTRACT

A modified and improved lithium cobalt oxide sputtering target with reduced resistivity is described. Unique modifications to the composition of the lithium cobalt oxide target allow adjustment or fine-tuning of the resistance of the target not previously possible. Incorporation of a controlled amount of one or more conductive materials into the lithium cobalt oxide composition is described alone or in combination with altering the stoichiometric ratio of Li:Co to significantly reduce resistivity and thereby enhance conductivity of the target. The result is a modified sputtering target capable of sputtering lithium-containing thin films that does not exhibit deterioration of their properties by virtue of elevated levels of conductive containing material incorporated into the target.

### RELATED APPLICATIONS

The present application claims priority from U.S. Application Ser. No. 61/946,286, filed Feb. 28, 2014, which is incorporated by reference herein in its entirety.

### FIELD OF THE INVENTION

The present invention relates to novel and improved lithium cobalt oxide sputtering targets configured to deposit lithium-containing thin films. Particularly, the invention relates to lithium cobalt oxide sputtering target assemblies that incorporate a predetermined amount of one or more conductive elements to lower resistance by a defined amount.

### BACKGROUND OF THE INVENTION

Lithium ion batteries have found utility in various applications, including automobiles, such as hybrid and electric vehicles. The emergence of lithium (Li) ion batteries can be attributed to several of its bulk properties, including high power density, low self-discharge rate and favorable charge-discharge cycle performance. The bulk properties affect the battery capacity and use life. Key variables which can affect the performance of the bulk properties include Li-ion diffusivity. As a result, Li-ion battery development has primarily focused on Li-containing materials having suitable Li-ion diffusivity. Materials of interest include LiCoO2, LiMn2O4 and LiFePO4. Of these materials, LiCoO2 has been determined to exhibit superior Li-ion diffusivity compared to LiMn2O4 and LiFePO4. As a result, LiCoO2 has emerged as the preferred precursor material for new lithium bulk battery applications within the electronics industry.

The suitability of LiCoO2 for use in battery technology also extends to thin film lithium battery applications, including MEMS and CMOS chip miniaturization. “Thin film lithium” as used herein and throughout the specification means a Li-containing film incorporated within a thin film battery having a total thickness of about 170 microns or less. FIG. 1 shows a generalized structure of a thin film battery consisting of multiple layers each at predefined thicknesses. The layers are in a stacked configuration that produces the resultant thin film battery assembly or structure. LiCoO2 is a required layer of the assembly. The LiCoO2 serves as the cathode in the battery and is shown situated between a metal foil substrate and an electrolyte. FIG. 1 shows that the size constraint for thin film lithium batteries can be appreciated by a comparison to a typical human hair having an effective diameter of 80 microns. The LiCoO2 film must have a predefined size so as to not cause the overall battery assembly to exceed the maximum allowable size for the thin film battery.

The required thin film lithium can be generally deposited by conventional sputtering target techniques, whereby a LiCoO2 sputtering target assembly, defined as the LiCoO2 sputtering target bonded to a backing plate, can be used to deposit the required thin film lithium. The term “sputtering target” and “target” may be used interchangeably herein and throughout the specification to designate a lithium cobalt oxide target. The term “lithium cobalt oxide target” as used herein and throughout the specification is intended to refer a target represented by the general formula LixCoyO2 where x and y are greater than 0 such that they can take on any value, dependently or independently of each other, thereby allowing a range of stoichiometric ratios of Li:Co to be utilized. With regards to sputtering targets to produce Li thin films, a D.C. (direct current) magnetron sputter system can be employed. The LixCoyO2 sputtering target is generally represented by the formula LiCoO2 and forms a part of a cathode assembly that, together with an anode, is placed in an evacuated chamber filled with an inert gas, preferably argon. Magnets are disposed above the LiCoO2 sputtering target, and a switch for connecting target backing plate to a D.C. voltage source. A substrate support is positioned below LiCoO2 sputter target within the chamber. In operation, a high voltage electrical field is applied across the cathode and the anode. The inert gas is ionized by collision with electrons ejected from the cathode. Positively charged gas ions are attracted to the cathode and, upon impingement with the target surface, these ions dislodge the target material. The dislodged target material traverses the evacuated enclosure and deposits as a LiCoO2 thin film on the desired substrate, which is normally located close to the anode.

Although D.C. sputtering can deposit LiCoO2 thin films, several drawbacks exist to conventional LiCoO2 sputtering target assemblies. Of primary concern, the conventional LiCoO2 sputtering targets possess unacceptably high resistivity, which can cause the target to act as an insulator. In such cases, the impedance of the target deteriorates sputtering rate to a point where sputtering of the target is not possible utilizing D.C. power. The effect is unacceptably low conductivity LiCoO2 targets which cannot be sputtered. Even if sputtering can be possible, today's LiCoO2 targets are producing films with unacceptable properties not suitable for their end-use in a thin film battery.

In view of the drawbacks, there is a growing need for improved LiCoO2 targets having significantly decreased resistivity.

### SUMMARY OF THE INVENTION

The invention may include any of the following aspects in various combinations and may also include any other aspect of the present invention described below in the written description.

In a first aspect, a sputtering target assembly for thin film lithium cobalt oxide deposition is provided. The assembly includes a backing plate is bonded to a surface of a solidified target material. The solidified target material is derived from a composition comprising lithium cobalt oxide represented by the general formula LiₓCoO₂, where x has a value of 1 or greater. The composition is further defined by a purity of 99% LiₓCoO₂ or higher. The solidified target material is characterized by a theoretical density of 98% or greater and a particle size of up to 10 microns. The solidified target material further comprises one or more conductive materials incorporated into the composition at a predetermined amount to reduce resistance of the solidified target material and thereby enhance conductivity during sputtering of said solidified target material in comparison to a (lithium cobalt oxide) target that is characterized by the absence of incorporation of said one or more conductive materials.

In a second aspect, a sputtering target assembly for thin film lithium cobalt oxide deposition is provided. The assembly comprises a backing plate bonded to a surface of a solidified target material. The solidified target material is derived from a composition comprising lithium cobalt oxide represented by the general formula LixCoyO₂. The composition is further defined by a predetermined stoichiometric ratio of Li:Co where x and y are both greater than 0. The solidified target material is characterized by a theoretical density of 98% or greater and a particle size of up to 10 microns. The LixCoyO₂ composition further comprises one or more conductive materials incorporated therein at a predetermined amount to lower resistance of the solidified target material and thereby enhance conductivity during sputtering of said solidified target material in comparison to a (lithium cobalt oxide) target without incorporation of said one or more conductive materials.

In a third aspect, a sputtering target assembly for thin film lithium deposition is provided. The target assembly includes a backing plate bonded to a surface of a solidified target material. The solidified target material is derived from a composition comprising lithium cobalt oxide represented by the general formula LiCoO₂. The solidified target material is characterized by a theoretical density of 98% or greater and a particle size of up to 10 microns. The LixCoyO₂ composition is further characterized by the absence of an organic binder and defined by a predetermined stoichiometric ratio of Li:Co of less than about 1:1 as defined by x by less being than y to lower resistance of the solidified target material and thereby enhance conductivity during sputtering of said solidified target material to deposit thin film lithium in comparison to a (lithium cobalt oxide) target represented by LiCoO₂ that is characterized by the absence of incorporation of said one or more conductive materials.

Other aspects, features and embodiments of the disclosure will be more fully apparent from the ensuing description and appended claims.

### BRIEF DESCRIPTION OF THE DRAWINGS

The objectives and advantages of the invention will be better understood from the following detailed description of the preferred embodiments thereof in connection with the accompanying figures wherein like numbers denote same features throughout and wherein:

FIG. 1 shows a thin film battery in which LiCoO2 serves as the cathode;

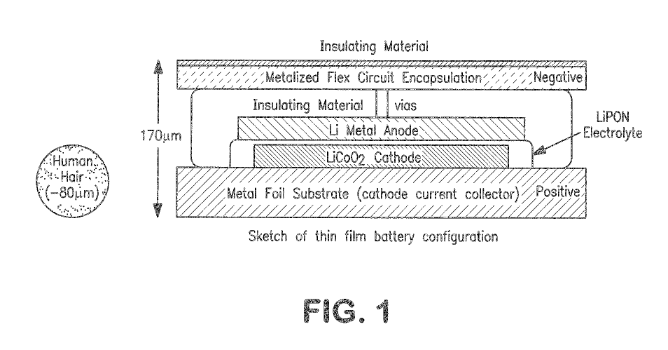

FIG. 2 shows a schematic of the assembly of tiles bonded to a backing plate, in which each of the tiles has a LiCoO2 composition prepared in accordance with the principles of the present invention;

FIG. 3 shows the meter and probe taking resistance measurements along the assembly of tiles;

FIG. 4 shows a graphical relationship of target resistance versus addition of carbon black empirically determined by working examples; and

FIG. 5 shows a typical microstructure of LiCoO2 with 3.5 wt % carbon black. The density is close to 100% of theoretical density.

### DETAILED DESCRIPTION OF THE INVENTION

The disclosure is set out herein in various embodiments, and with reference to various features and aspects of the invention. The disclosure contemplates such features, aspects and embodiments in various permutations and combinations, as being within the scope of the disclosure. The disclosure may therefore be specified as comprising, consisting or consisting essentially of, any of such combinations and permutations of these specific features, aspects and embodiments, or a selected one or ones thereof.

Unless indicated otherwise, all percentages are expressed herein as wt % based on the total weight of target.

The present invention is directed to a modified lithium cobalt oxide sputtering target with reduced resistivity and improved sputtering performance over conventional lithium cobalt oxide targets. The modified lithium cobalt oxide sputtering target incorporates one or more conductive materials into the lithium cobalt oxide composition without deleteriously affecting the properties of the solidified target or the resultant film that is deposited from sputtering of the target.

In one embodiment of the present invention, the one or more conductive materials is selected to be a carbon-containing material, such as carbon black. The carbon black is incorporated into the lithium cobalt oxide target. The carbon black is incorporated at a predetermined amount defined as that amount which reduces resistivity without substantially deteriorating sputter performance and conductance of the target so as to not degrade the properties of the resultant film sputtered from the inventive target. In a preferred embodiment, carbon black is introduced into the lithium cobalt oxide target in a predetermined amount of at least about 3.5 wt % based on a total weight of the solidified target material. Resistance of the solidified target decreases upon incorporation of the carbon black at a level that is at least about 3.5 wt %. Generally speaking, the addition of the conductive containing materials at or beyond the minimum amount can significantly alter resistivity. Depending on the selected stoichiometric ratio of Li:Co employed to form the lithium cobalt oxide composition, relatively small incremental additions of the carbon black beyond the minimum amount can significantly enhance conductivity of the solidified target. Preferably, the resistance is reduced to a level at or below 2E5 ohms when adding at least about 3.5 wt % carbon black. Incorporation of the carbon-containing material, such as a carbon black into the target, is a counterintuitive approach, as conventional targets explicitly limit the maximum amount of carbon to a ppm level or entirely avoid carbon incorporation into the solidified lithium cobalt oxide target in order to avoid contamination by carbon and any resultant degradation of target sputtering performance.

In some instances, depending at least in part on the stoichiometric ratio of Li:Co in the lithium cobalt oxide, the predetermined amount of the conductive materials can be further defined by an upper limit to the amount of conductive material which can be incorporated into the target. The present invention recognizes that there may be instances when exceeding an upper limit may deleteriously affect the properties of the solidified target and/or the resultant film deposited from sputtering of the solidified target by an amount where the benefits of resistance lowering is entirely negated and therefore not realized. Additionally, purity of the as-deposited film may be substantially impacted if elevated levels of the conductive material sputter ultimately become in-film deposits which contaminate the film. By way of example, a lithium cobalt oxide having a composition represented by formula LiCoO2 should not incorporate carbon black at a level exceeding 15 wt %. Accordingly, while the incorporation of the conductive materials lowers resistivity, it can also deteriorate the target structure and sputter performance when added in amounts that exceed an upper limit. The present invention recognizes that the addition of conductive materials, which are carbon-containing such as carbon black, in controlled amounts within a prescribed range does not deteriorate film purity levels; does not impede Li-ion diffusivity in the thin film; and does not interfere with the intended electrochemical mechanism of the thin film battery.

The carbon-containing materials specifically exclude incorporation of substantial amounts of non-carbon containing material such as, for example, organic constituents (e.g., acetate organic binders and derivatives thereof) or other additives which may degrade target structure and performance. Preferably, such non-carbon containing material is maintained at the ppm level, in particularly less than about 10000 ppm, more preferably less than about 5000 and most preferably less than about 1000 ppm. In this manner, the lithium cobalt oxide composition retains the reduced resistivity without the incorporation of the carbon-containing material deleteriously affecting target structure (e.g., bond strength, macrostructure and microstructure) and performance during sputtering.

In a preferred embodiment, when incorporating carbon-containing material at a level of at least about 3.5 wt %, the lithium cobalt oxide has a composition that is represented by the formula LiCoO2 in which the stoichiometric ratio of Li:Co is approximately 1. In accordance with the principles of the present invention, the stoichiometric ratio of Li:Co can be altered to be greater than 1:1 or less than 1:1, depending on the type of conductive materials utilized or the level at which said conductive materials are incorporated during formation of the solidified target. The ability to modify the stoichiometric ratio in combination with the types and amounts of conductive materials can further reduce resistivity and enhance conductivity, thereby optimizing the overall target sputter performance.

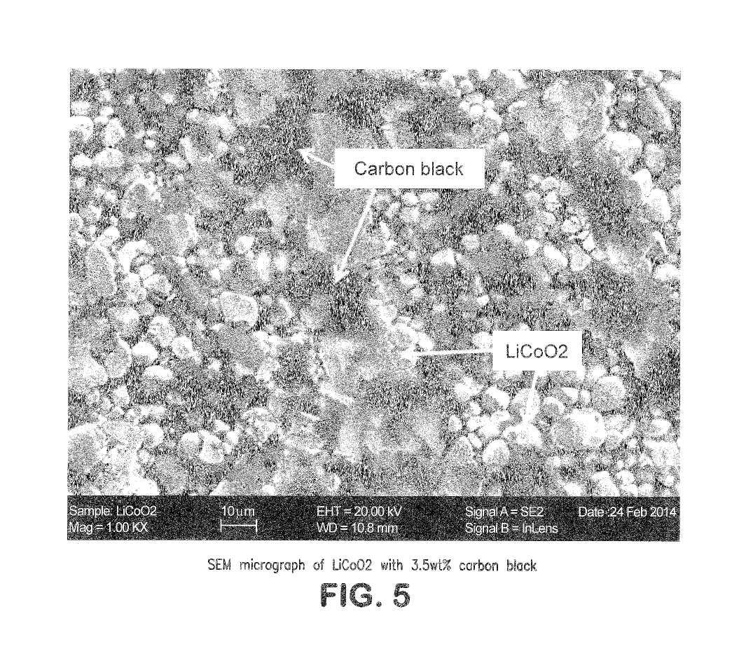

The lithium cobalt oxide composition (i.e., the composition prior to incorporation of the conductive materials) has a purity level of 99% or greater with a particle size of up to about 10 microns, preferably less than 7 microns. The lithium cobalt oxide composition is further defined by a theoretical density of 98% or greater. The microstructure of LiCoO2 with 3.5 wt % carbon black is shown in FIG. 5. LiCoO2 particulates are indicated by the arrow. The black color phase is carbon black (as indicated by the arrow) which is shown uniformly distributed within the LiCoO2 matrix. The target material (i.e., lithium cobalt oxide material) in combination with the carbon black or other suitable one or more conductive materials can be solidified by any known method, such as pressing, which can be performed by any suitable means known in the art, including vacuum hot pressing or cold isostatic pressing followed by sintering. It should be understood that the principles of the present invention are applicable to any type solidified target, including planar targets, rotary targets or monolithic targets. Rotary targets are preferably solidified by a press and sinter operation that allows the lithium cobalt oxide starting material to be consolidated. The lithium cobalt oxide material prior to consolidation may be in any form, including granular, particulate or powder form. Preferably, the lithium cobalt oxide material is in a powder form so as to eliminate the need to utilize an organic binder for purposes of assisting with consolidation of the starting material into a solidified mass of target. Planar targets are preferably vacuum hot pressed under suitable time, temperature and pressure conditions that enable sufficient consolidation of the lithium cobalt oxide powder to form the solidified target.

The conductive containing materials can be incorporated into the lithium cobalt oxide composition by any suitable means. For example, the materials can be blended by suitable blending means, such as any known mechanical blending system and method. In another example, the conductive containing material is sprayed or coated onto individual particles of the lithium cobalt oxide. Preferably, the carbon black has a smaller particle size than the lithium cobalt oxide particles to ensure that a majority of the exposed surfaces of the lithium cobalt oxide particles are coated or sprayed by the carbon black. Spraying or coating may improve distribution of the conductive containing materials within the lithium cobalt oxide composition so as to produce a resultant solidified target with improved uniform resistivity.

The present invention contemplates various means for adjusting or fine-tuning the desired reduction in resistivity which take into account Li:Co stoichiometric ratio. The stoichiometric ratio can determine how much conductive containing material to incorporate into the target having a LixCoyO2 composition and vice versa. In one embodiment, reduction of resistivity can decrease by orders of magnitude when the Li:Co stoichiometric ratio remains about 1:1 and the carbon black or other suitable conductive material is incorporated into the LiCoO2 composition at a level of at least about 3.5 wt %. Alternatively, the Li:Co stoichiometric ratio can be adjusted downwards below a Li:Co stoichiometric ratio of 1:1, when incorporating carbon black or other conductive materials at about 3.5 wt % or lower to lower resistivity of the solidified target and therefore enhance conductivity.

Generally speaking, when the ratio of Li:Co is less than 1, relatively less carbon black or other suitable conductive materials may be required to be incorporated into the lithium cobalt oxide composition. In one embodiment, the Li:Co stoichiometric ratio is about 0.5 while the carbon black is incorporated into the Li_{0.5}CoO₂ composition at a level less than 3.5 wt %, and more preferably between 1-3 wt %. In another embodiment, the Li:Co stoichiometric ratio is about 1 while the carbon black is incorporated into the LiCoO₂ composition at a level of about 3.5 wt %. These embodiments demonstrate the interrelationship between Li:Co stoichiometry and carbon black additions which can be utilized to reduce resistivity in a controlled manner.

The present invention recognizes that conductive materials such as carbon black which are added to the composition at 3.5 wt % or more tend to decrease resistivity by orders of magnitude. However, a reduction in resistivity by orders of magnitude (i.e., adjustment) may not be required nor ideal for certain end-use sputtering applications. There may be instances where the resistivity of the lithium cobalt oxide targets needs only to be fine-tuned (i.e., slightly reduced in comparison to a lithium cobalt oxide target defined as LiCoO2 that does not incorporate one or more conductive materials). Accordingly, in one embodiment, the present invention solely relies on adjusting the Li:Co stoichiometric ratio of the lithium cobalt oxide composition without adding any conductive materials to dial-in a slightly reduced resistivity. For instance, a composition represented by the formula LiₓCo_{y}O₂where x is less than y may be utilized so as to create a stoichiometric ratio of Li:Co of less than about 1:1 but equal to or greater than about 0.5:1 in order to fine-tune the resistivity.

In one embodiment, Li:Co stoichiometric ratios can vary in a range from about 0.25 to about 2 or higher, more preferably from about 0.5 to about 1.5 and more preferably from about 0.5 to about 1, while the carbon black is added to the LixCoyO₂ composition at a level of about 3.5 wt %. Depending on whether the Li:Co ratio remains at 1:1; lower than 1:1; or higher than 1:1, the appropriate amount of conductive material can be determined for introduction into the lithium cobalt oxide (LiₓCoyO2) composition. The present invention therefore allows the ability to reduce resistivity to customized levels and in a controlled manner (i.e., adjusting orders of magnitude versus fine-tuning a slightly lower resistivity), a technique not previously recognized nor demonstrated with conventional lithium cobalt oxide targets.

The present invention offers a unique solution to the problem of reducing resistivity in LixCoyO2 sputtering targets. Furthermore, the ability for the present invention to selectively adjust or fine-tune the resistance in a way suitable for the intended application has not been possible with conventional LixCoyO2 sputtering targets. The inventive targets are configured to produce high quality lithium-containing thin films in a controlled manner onto a thin lithium film battery without deleteriously affecting the lithium-containing thin film or the thin film battery. Furthermore, the lithium-containing thin films can be sputtered onto thin film batteries having a thickness of 170 microns or less. As a result, the present invention offers the ability for new generation electronic devices to become even smaller in size by virtue of the ability to sputter the targets of the present invention to produce lithium-containing thin films.

In an alternative embodiment, other suitable dopant materials may be utilized to improve conductivity LixCoyO2 sputtering targets without inducing a substantial loss of the oxide phase therein. Such materials may include ZnO, SnO2, Al2O3 and MgO.

The working examples below demonstrate the addition of a carbon black within a prescribed range produces a solidified target having a lithium cobalt oxide composition with a lower resistivity by orders of magnitude without deleteriously affecting properties of the solidified target. Meaningful comparisons were possible by maintaining the same stoichiometric ratio of Li:Co (1:1); maintaining the same vacuum hot pressing procedure; and maintaining the same blending methodology throughout all of the tests. It should be understood that the working examples are not intended in any way to limit the scope of the present invention, but rather are intended to illustrate principles of the present invention.

### Comparative Example 1

### Solidified Pressed Blank Having a LiCoO2 Composition with 0 wt % Carbon Black

A lithium cobalt oxide composition represented by the formula LiCoO2 and therefore having a stoichiometric ratio of Li:Co of 1:1 was pressed to consolidate the powder and produce a solidified disk. The LiCoO2 powder that was utilized was commercially available and obtained from Nippon Chemical, located in Japan. No carbon black was mixed with the LiCoO2. The LiCoO2 powder had a purity of 99.5% and a particle size of less than 10 microns. 100 grams LiCoO2 powder was consolidated by vacuum hot pressing in a 2.5 inch diameter graphite die by applying 1 ksi pressure at 800° C. for 4 hours. The vacuum hot pressing consolidated the LiCoO2 powder and produced a disk having a diameter of 2.5 inch and a thickness of 0.32 in. The pressed disk was then machined by a grinder to remove surface contamination from the graphite die and also create flat surfaces, thereby reducing the dimension to 2 in diameter×0.25 in thickness.

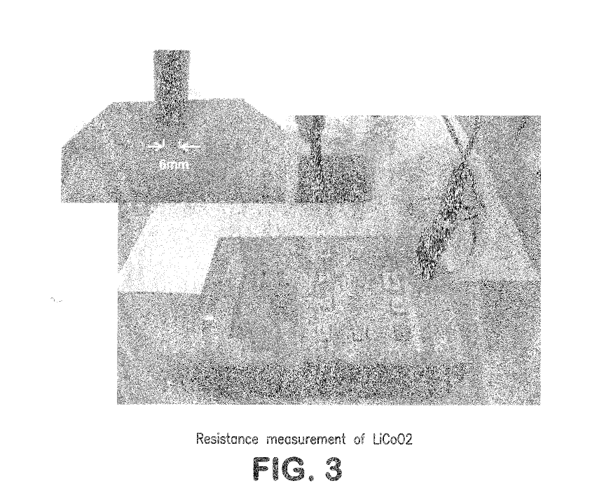

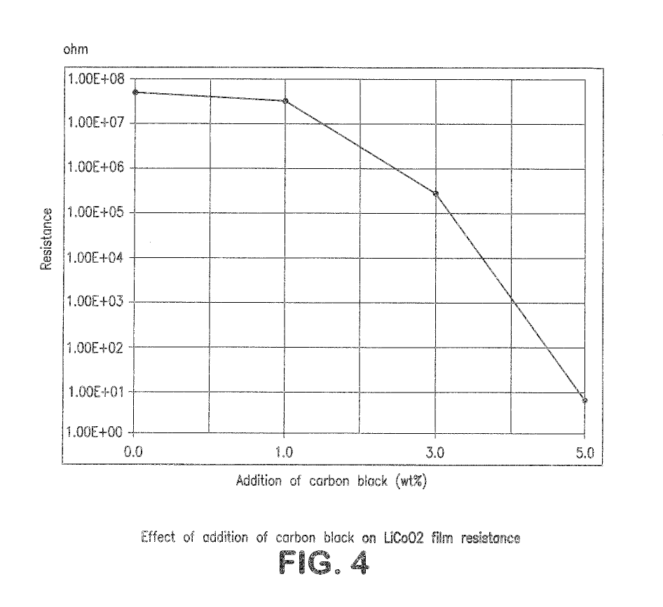

The resistance of the disk was measured using a resistivity meter that was made and sold by Prostat Corp. (Bensenville, Ill.). The meter consisted of 2 probes which were spaced apart 6 mm, as shown in FIG. 3. During the surface resistance measurement, the probes contacted the surface of the various blanks in a generally perpendicular orientation, as shown by the arrow in FIG. 3. Four positions on the disk surface were measured. The resistance ranged from 5E7 ohms to 4E8 ohms. The averaged measured resistance was determined to be approximately 1E8 ohms, which is considered unacceptably high for adequate D.C. sputtering. FIG. 4 shows the resistance without addition of carbon black. This resistance measured value was believed to be representative of a solidified pressed blank having a LiCoO2 composition without incorporation of carbon black or any other suitable conductive containing material, and would therefore serve as the baseline against which the LiCoO2 targets of the present invention could be compared and evaluated.

### Example 1

### Solidified Pressed Blank Having a LiCoO2 Composition with 1.0 wt % Carbon Black

A lithium cobalt oxide composition represented by the formula LiCoO2 and therefore having a stoichiometric ratio of Li:Co of 1 was pressed to consolidate the powder and produce a solidified disk. The LiCoO2 powder that was utilized was commercially available and obtained from Nippon Chemical, located in Japan. The LiCoO2 powder had a purity of 99.5% and a particle size of less than 10 microns. The carbon black powder that was utilized was commercially available and obtained from Timcal Graphite and Carbon. The carbon black had a purity of 99% and a particle size of less than 45 microns. 99 grams LiCoO2 powder and 1 grams carbon black were blended to produce a blend having a 1.0 wt % carbon content based on a total weight of the blend. The LiCoO2 powder and carbon black powder were simultaneously loaded in a 1-qt milling jar with 50 grams ZrO2 media. The materials were blended for 4 hours to ensure the two powders were uniformly mixed. After blending, the ZrO2 media was separated from the mixed powder by sieve. The mixed powder was consolidated by vacuum hot pressing to produce a disk by utilizing the procedure as described in Comparative Example 1. The pressed disk was then machined by utilizing the procedure as described in Comparative Example 1.

The resistance on the surface of the disk was measured using a resistivity meter that was made and sold by Prostat Corp. (Bensenville, Ill.). The meter consisted of 2 probes which were spaced apart 6 mm, as shown in FIG. 3. Four positions on the disk surface were measured. The resistance ranged from 3E6 ohm to 1E8 ohm. The averaged measured resistance was 4.5 E7 ohm, which was determined to be slightly less than the measured resistance of Comparative Example 1. No detrimental impact to the target structure was observed by virtue of the higher amount of carbon. FIG. 4 shows the measured resistance value corresponding to an addition of 1 wt % carbon black. This test demonstrates that the addition of carbon black was able to noticeably lower resistance of a pressed blank that was formed from a LiCoO2 composition.

### Example 2

### Solidified Pressed Blank Having a LiCoO2 Composition with 3.0 wt % Carbon Black

A lithium cobalt oxide composition represented by the formula LiCoO2 and therefore having a stoichiometric ratio of Li:Co of 1 was pressed to consolidate the powder and produce a solidified disk. The LiCoO2 powder that was utilized was commercially available and obtained from Nippon Chemical, located in Japan. The LiCoO2 powder had a purity of 99.5% and a particle size of less than 10 microns. The carbon black powder that was utilized was commercially available and obtained from Timcal Graphite and Carbon. The carbon black had a purity of 99% and a particle size of less than 45 microns. 97 grams LiCoO2 powder and 3 grams carbon black were blended to produce a blend having a 3.0 wt % carbon content based on a total weight of the blend. The LiCoO2 powder and carbon black powder were simultaneously loaded in a 1-qt milling jar with 50 grams ZrO2 media. The materials were blend for 4 hours to ensure the two powders were uniformly mixed. After blending, the ZrO2 media was separated from the mixed powder by sieve. The mixed powder was consolidated by vacuum hot pressing to produce a disk by utilizing the procedure as described in Comparative Example 1.

The resistance on the surface of disk was measured using a resistivity meter that was made and sold by Prostat Corp. (Bensenville, Ill.). The meter consisted of 2 probes which were spaced apart 6 mm, as shown in FIG. 3. During the surface resistance measurement, the probes contacted the surface of the various blanks in a generally perpendicular orientation, as shown by the arrow in FIG. 3. Four positions on disk surface were measured. The resistance ranged from 3E5 ohm to 6E5 ohm. The averaged measured resistance was 4.8 E5 ohm, which was determined to be significantly less than the measured resistance of Comparative Example 1. FIG. 4 shows the measured resistance value corresponding to an addition of 3.0 wt % carbon black. No detrimental impact to the target structure was observed by virtue of the higher amount of carbon. This test demonstrates that the addition of carbon black was able to noticeably lower resistance by orders of magnitude compared to 1.0 wt % carbon addition into a pressed blank that was formed from a LiCoO2 composition.

### Example 3

### Solidified Pressed Blank Having a LiCoO2 Composition with 5.0 wt % Carbon Black

A lithium cobalt oxide composition represented by the formula LiCoO2 and having a stoichiometric ratio of Li:Co of 1 was pressed to consolidate the powder and produce a solidified disk. The LiCoO2 powder that was utilized was commercially available and obtained from Nippon Chemical, Japan. The LiCoO2 powder had a purity of 99.5% and a particle size of less than 10 microns. The carbon black powder that was utilized was commercially available and obtained from Timcal Graphite and Carbon. The carbon black had a purity of 99% and a particle size of less than 45 microns. 95 grams LiCoO2 powder and 5 grams carbon black were blended to produce a blend having a 5.0 wt % carbon content based on a total weight of the blend. The LiCoO2 powder and carbon black powder were simultaneously loaded in a 1-qt milling jar with 50 grams ZrO2 media. The materials were blended for 4 hours to ensure the two powders were uniformly mixed. After blending, the ZrO2 media was separated from the mixed powder by a sieve.

The mixed powder was consolidated by vacuum hot pressing to produce a disk by utilizing the procedure as described in Comparative Example 1.

The resistance on the surfaces of disk was measured using a resistivity meter that was made and sold by Prostat Corp. (Bensenville, Ill.). The meter consisted of 2 probes which were spaced apart 6 mm, as shown in FIG. 3. During the surface resistance measurement, the probes contacted the surface of the various blanks in a generally perpendicular orientation, as shown by the arrow in FIG. 3. Four positions on the disk surface were measured. The resistance ranged from 0.5 ohm to 0.8 ohm. The averaged measured resistance was 0.6 ohm, which was determined to be significantly less than the measured resistance of Comparative Example 1. FIG. 4 shows the measured resistance value corresponding to an addition of 5.0 wt % carbon black. No detrimental impact to the target structure was observed by virtue of the higher amount of carbon. This test demonstrates that the addition of carbon black was able to noticeably lower resistance by orders of magnitude compared to 3.0 wt % carbon addition into a pressed blank that was formed from a LiCoO2 composition.

From the above working examples, a graphical relationship that correlates resistance and the additions of carbon black wt % can be established for a range of carbon black weight percentages ranging from 0 wt % to 5 wt %. The graphical relationship as shown in FIG. 4 can be used to estimate with reasonable accuracy the amount of carbon black required to reduce resistivity for a lithium cobalt oxide target represented by the formula LiCoO2. Other graphs for lithium cobalt oxide targets represented by the formula LixCoyO2 where x and/or y do not equal 1 can be constructed using carbon black or another conductive containing material.

It should be understood from the above working examples that the addition of carbon or other conductive containing material lowers resistivity in comparison to a (lithium cobalt oxide) target in which the stoichiometric ratio of Li:Co can take on any value. Of particular significance is the ability to add a predefined amount of conductive containing material (e.g., at least 3.0 wt % carbon black) and observe a reduction in resistance by orders of magnitude in comparison to a (lithium cobalt oxide) target in which the stoichiometric ratio of Li:Co can take on any value.

### Example 4

### Solidified Pressed Blank Having a LiCoO2 Composition with 3.5 wt % Carbon Black

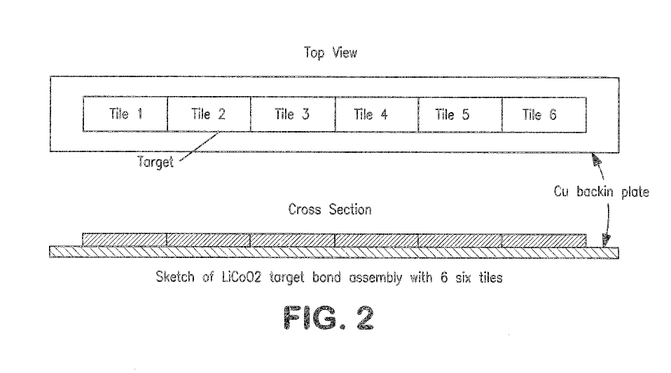

A lithium cobalt oxide composition represented by the formula LiCoO2 and therefore having a stoichiometric ratio of Li:Co of 1 was pressed to consolidate the powder and produce solidified disks. The LiCoO2 powder that was utilized was commercially available and obtained from Nippon Chemical, Japan. The LiCoO2 powder had a purity of 99.5% and a particle size of less than 10 microns. The carbon black powder that was utilized was commercially available and obtained from Timcal Graphite and Carbon. The carbon black had a purity of 99% and a particle size of less than 45 microns. 965 grams LiCoO2 powder and 35 grams carbon black were blended to produce a blend having a 3.5 wt % carbon content based on a total weight of the blend. The LiCoO2 powder and carbon black powder were simultaneously loaded in a 1.6 gal milling jar with 500 grams ZrO2 media. The materials were blend for 4 hours to ensure the two powders were uniformly mixed. After blending, the ZrO2 media was separated from the mixed powder by sieve. The LiCoO2 powder and carbon were blended to produce a blend containing 3.5 wt % carbon based on the total weight of the blend. 1000 grams mixed powder was consolidated for one disk by vacuum hot pressing in a 5.5 inch diameter graphite die by applying 1 ksi pressure at 800° C. for 4 hours. By utilizing the above process, six disks were produced each having a diameter of 5.5 inches and a thickness of 0.32 inch. 6 rectangular-shaped tiles or blanks were machined from the disks. Each of the 6 tiles or blanks had a dimension of 3.75 in×3.5 in×0.236 in. The 6 tiles were bonded to a copper backing plate to produce a target assembly. The bond surface of the target assembly was created by depositing 3 layers of Ti, NiV and Ag and then affixing the blanks to the copper backing plate with indium solder. The layers of Ti, NiV and Ag served as a wetting agent for the indium. FIG. 2 shows a schematic of the assembly of tiles onto the backing plate. The assembly had dimensions of 22.5 in×3.5 in.

The resistance along the surfaces of the assembly of tiles was measured using a resistivity meter that was made and sold by Prostat Corp. (Bensenville, Ill.). The meter consisted of 2 probes which were spaced apart 6 mm, as shown in FIG. 3. During the surface resistance measurement, the probes contacted the surface of the various blanks in a generally perpendicular orientation, as shown by the arrow in FIG. 3. Four measurements were taken on each tile along the assembly of FIG. 2. The resistance ranged from 1E4 ohm to 3.1E5 ohm. The averaged measured resistance was 2E5 ohm, which was determined to meet the resistance required of DC sputtering.

While it has been shown and described what is considered to be certain embodiments of the invention, it will, of course, be understood that various modifications and changes in form or detail can readily be made without departing from the spirit and scope of the invention. It is, therefore, intended that this invention not be limited to the exact form and detail herein shown and described, nor to anything less than the whole of the invention herein disclosed and hereinafter claimed.

1. A sputtering target assembly for lithium-containing thin film deposition, comprising:
a backing plate bonded to a surface of a solidified target material;
said solidified target material derived from a composition comprising lithium cobalt oxide represented by the general formula LiₓCoO₂, where x has a value of 1 or greater, and wherein said composition is further defined by a purity of 99% LiₓCoO₂ or higher;
said solidified target material characterized by a theoretical density of 98% or greater and a particle size of up to 10 microns; and
said solidified target material further comprising one or more conductive materials incorporated into the composition at a predetermined amount to reduce resistance of the solidified target material and thereby enhance conductivity during sputtering of said solidified target material in comparison to a (lithium cobalt oxide) target that is characterized by the absence of incorporation of one or more conductive materials.

2. The sputtering target assembly of claim 1, wherein said one or more conductive materials consisting essentially of carbon black that is incorporated at the predetermined amount, said predetermined amount within a prescribed range that is at least equal to or greater than a lower limit but less than or equal to an upper limit.

3. The sputtering target assembly of claim 2, wherein said carbon black is at least about 3.5 wt % or greater based on a total weight of the solidified target material.

4. The sputtering target assembly of claim 1, wherein said composition comprising lithium cobalt oxide is represented by the general formula LiₓCoO₂, where x has a value of 1.

5. The sputtering target assembly of claim 1, wherein said composition comprises lithium cobalt oxide in a form of powder particles, and further wherein said one or more conductive materials comprises carbon, said carbon coated onto at least a portion of the powder particles.

6. The sputtering target assembly of claim 1, wherein said one or more conductive materials comprises carbon black at said predetermined amount of about 3.5 wt % or higher based on the total weight of the solidified target material to lower said resistance of the solidified target material to at least about 2E5 ohms or lower in comparison to a (lithium cobalt oxide) target that is characterized by the absence of incorporation of a carbon-containing material.

7. The sputtering target assembly of claim 1, wherein said one or more conductive materials comprises carbon black at said predetermined amount of about 3.5 wt % or higher based on the total weight of the solidified target material to lower said resistance of the solidified target material to at least about 2E5 ohms or lower, and further wherein said composition comprises lithium cobalt oxide represented by the general formula LiₓCoO₂, where x has a value of 1.

8. The sputtering target assembly of claim 1, said surface of a solidified target material being cylindrical shaped, said cylinder shaped solidified target material having an inner surface bonded to an outer surface of said backing plate.

9. A sputtering target assembly for lithium-containing thin film lithium deposition, comprising:
a backing plate bonded to a surface of a solidified target material;
said solidified target material derived from a composition comprising lithium cobalt oxide represented by the general formula LixCoyO₂, wherein said composition is further defined by a predetermined stoichiometric ratio of Li:Co where x and y are both greater than 0;
said solidified target material characterized by a theoretical density of 98% or greater and a particle size of up to 10 microns; and
said LixCoyO₂ composition further comprising one or more conductive materials incorporated therein at a predetermined amount to lower resistance of the solidified target material and thereby enhance conductivity during sputtering of said solidified target material in comparison to a (lithium cobalt oxide) target that is characterized by the absence of incorporation of said one or more conductive materials.

10. The sputtering target assembly of claim 9, wherein said predetermined stoichiometric ratio of Li:Co ranges from about 0.5:1 to about 2:1.

11. The sputtering target assembly of claim 10, wherein said composition is characterized by the absence of an organic binder.

12. The sputtering target assembly of claim 9, wherein said predetermined stoichiometric ratio of Li:Co is at least about 1:1 and said one or more conductive materials consisting essentially of a carbon-containing material having a carbon content of at least about 3.5 wt % based on a total weight of said solidified target material so as to lower a resistance of said solidified target material to 2E5 ohms or lower in comparison to a (lithium cobalt oxide) target that is characterized by the absence of incorporation of said carbon-containing material.

13. The sputtering target assembly of claim 9, wherein said predetermined amount is within a prescribed range that is at least equal to or greater than a lower limit but less than or equal to an upper limit

14. A sputtering target assembly for thin film lithium deposition, comprising:
a backing plate bonded to a surface of a solidified target material;
said solidified target material derived from a composition comprising lithium cobalt oxide represented by the general formula LixCoyO₂;
said solidified target material characterized by a theoretical density of 98% or greater and a particle size of up to 10 microns; and
said LixCoyO₂ composition further characterized by the absence of an organic binder and defined by a predetermined stoichiometric ratio of Li:Co of less than about 1:1 as defined by x being less than y so as to lower resistance of the solidified target material and thereby enhance conductivity during sputtering of said solidified target material to deposit lithium-containing thin film in comparison to a (lithium cobalt oxide) target represented by LiCoO₂ that is characterized by the absence of incorporation of said one or more conductive materials.

15. The sputtering target assembly of claim 14, wherein said predetermined stoichiometric ratio of Li:Co is about 0.5 to 1.

16. The sputtering target assembly of claim 14, wherein said composition comprises one or more carbon-containing conductive materials.

17. The sputtering target assembly of claim 16, wherein said carbon-containing conductive material is carbon black at 3.5 wt % or less based on a total weight of the solidified target material.

18. A film produced by the sputtering target assembly of claim 14, said film having a thickness of 170 microns or less.

19. A film produced by the sputtering target assembly of claim 17, comprising an absence of in-film carbon-containing particles.

20. A film produced by the sputtering target assembly of claim 1.
